(19) United States
(12) Patent Application Publication
(10) Pub. No.: US 2014/0311555 A1
(43) Pub. Date: Oct. 23, 2014

(54) ENCAPSULATION FOR PHOTOVOLTAIC MODULE

(71) Applicant: Stichting Energieonderzoek Centrum Nederland, Petten (NL)

(72) Inventors: Sytze Hessel Matthes Harkema, Petten (NL); Bert Plomp, Petten (NL)

(73) Assignee: Stichting Energieonderzoek Centrum Nederland, Petten (NL)

(21) Appl. No.: 14/346,907

(22) PCT Filed: Sep. 25, 2012
(86) PCT No.: PCT/NL2012/050672

§ 371 Date: Mar. 24, 2014

(30) Foreign Application Priority Data
Sep. 26, 2011 (NL) 2007474

(51) Int. Cl. H01L 31/048; H01L 31/0236

(52) U.S. Cl. CPC H01L 31/0481; H01L 31/02366
USPC 136/251; 438/65

(57) ABSTRACT

A photovoltaic module comprising a photovoltaic layer (2) with one or more photovoltaic cells and an encapsulation comprising a top foil (6). The photovoltaic layer (2) is provided with a texture layer (3), e.g. a front side metallization. The encapsulation further comprises a planarization layer (4) directly in contact with the photovoltaic layer (2) and texture layer (3). The planarization layer (4) levels all texture, enabling a top foil (6) being laminated with an adhesive to finalize the photovoltaic module.

### FIELD OF THE INVENTION

The present invention relates to the encapsulation of photovoltaic (PV) modules, it functions as transparent surface protective layer, especially for flexible thin film type of PV-technologies which are suitable for roll to roll production. More in particular, the present invention relates to a photovoltaic module comprising a photovoltaic layer with one or more photovoltaic cells and an encapsulation comprising a top foil, the photovoltaic layer being provided with a texture layer. In a further aspect, the present invention relates to a method for manufacturing a photovoltaic module, comprising providing a PV module having a photovoltaic layer with a (light receiving, planar) surface.

### BACKGROUND

European patent application EP-A-1 703 570 discloses encapsulation of photovoltaic cells and modules, wherein thermally curing polymers are used. An example of thermo curing polymers disclosed is ethylene vinyl acetate (EVA) which is applied at least on top of the PV cell, which is used to bond a layer of ethylene tetrafluoroethylene (ETFE) as protective outer layer (top foil).

American patent publication U.S. Pat. No. 4,497,974 discloses a method for making a thin film solar cell with a detached reflector. A photovoltaic module is disclosed with one or more cells and an encapsulation layer with a top foil. The PV layer is provided with a texture layer and the encapsulation layer comprises a planarization layer in contact with the texture layer. This enables the silver layer to be applied and act as a detached reflector. The planarization layer is disclosed as a layer of plastic which is spin coated or injection molded on top of the texture layer.

Photovoltaic cells and modules convert sunlight into electricity, it finds its application in the domestic areas for electricity production for households (typically 2 kWp of power per system) and also for large scale energy production at PV plants (>1 MWp). Typical service time for these devices is more than 20 years, this is also an indicative timescale on which panels can be cost efficient. The long lifetime and outdoor exposure will bring up several severe demands to photovoltaic systems.

The demands vary in scope, some are to ensure stable electricity output over the lifetime of the PV-device, others should guarantee the safety of the electrical systems for the end-users. Firstly the performance should be stable over 20 years of time, in general a total relative decrease in performance of 1% per year is accepted, so only 20% after 20 years. This is the sum of all the losses due to various degradation mechanisms that can occur, like reduction in transmission due to yellowing, surface erosion, local delamination, but also electrical degradation due to an increase of series resistance, lower shunt resistances, etc.

The system must also be safe after 20 years of outdoor exposure. Electrical safety must be provided by materials, preventing leakage currents and electrical shocks of the system to installers, end-users or maintenance providers. As a consequence PV-modules cannot exhibit any delamination or change in dielectric properties over it lifetime.

Most of the degradation mechanisms are promoted by the presence of water, oxygen, UV-light, high temperatures and thermal changes. Solutions which are cost effective and fulfill all demands are thereby scarce. The amount of allowable exposure differs per type of technology. Organic PV (OPV) is known to be intolerant to H₂O and O₂, other types of ‘thin film’ technologies (thickness of the absorber layer in general lower than 3 μm) like Cadmium Telluride (CdTe), Copper Indium Gallium Selenium (CIGS) and film Silicon (f-Si) are vulnerable to H₂O. These type of technologies need a different type of protection than crystalline Si technologies.

The combination of these severe demands result that nowadays only a small scope of materials is found to be applied for front-side encapsulation of PV-modules. A vast majority uses ethylene vinyl acetate (EVA) and glass on the front-side of modules. For light weight and flexible applications typically a combination of EVA and fluoropolymers like ethylene tetrafluoroethylene (ETFE) can be used. Alternative for EVA is polyvinyl butyral (PVB), generally used within so called ‘glass-glass’ modules, having glass on the front and back side of the module.

### SUMMARY OF INVENTION

All of the prior art solutions for (front side) encapsulation of PV modules need thermal processing steps of the modules at elevated temperature and during relatively long periods. For instance EVA needs to cure for typically 15 minutes at 150° C. For high speed processing of PV-modules like for instance roll-to-roll manufacturing this is undesirable.

The present invention seeks to provide an encapsulation of PV modules, e.g. at least for front side encapsulation, which allows a higher speed processing of the PV modules, while still providing excellent protection of the PV module.

According to the present invention, a photovoltaic module according to the preamble defined above is provided, wherein the encapsulation further comprises a planarization layer directly in contact with the photovoltaic layer and texture layer. The planarization layer levels all texture in the texture layer on top of the photovoltaic layer, enabling a top foil being easily laminated with an adhesive to make an encapsulated photovoltaic module.

In an embodiment, the planarization layer is a radiation curing coating, e.g. a UV-light or electron beam curing coating which is known to the skilled person as such. Radiation curing is a very fast process (in the order of seconds) and does not need any elevated temperature treatment. Thus, the manufacturing process of the entire photovoltaic module can be performed faster and more cost-effectively.

An adhesive layer is present on top of the planarization layer in a further embodiment, and the top foil is present on top of the adhesive layer. Such an adhesive layer can be easily applied in an industrial manufacturing process, e.g. using dry film lamination techniques.

The material of the top foil may be selected from the group of: a fluoropolymer, a polyester, a polyamide, an acrylate, a silicone or a glass in a further embodiment, and is e.g. made of any of the materials PET, PEN, ETFE, FEP.

In a further embodiment, the photovoltaic module further comprising a top coating on top of the top foil, e.g. functioning as a UV-light screening coating. The top coating is in a further embodiment a radiation curing coating.

The photovoltaic layer may comprise a first protection layer in the form of an inorganic dielectric layer in a further embodiment, which acts to protect the surface of the photovoltaic cells. Additionally, or alternatively, a second protection layer in the form of an inorganic dielectric layer is deposited on top of the planarization layer. In an even further embodiment, an additional planarization layer and a third protection layer is applied to the top foil (top or bottom side), the third protection layer being an inorganic dielectric layer. These water, oxygen or permeating molecule barrier type layers protect the underlying layers of the photovoltaic module.

In a further aspect, the present invention relates to a method for manufacturing a photovoltaic module, comprising providing a PV module having a photovoltaic layer with a surface on which a texture layer is present (e.g. a metallization layer). The method further comprises providing a planarization layer directly in contact with the photovoltaic layer and texture layer, curing the planarization layer using e.g. UV or electron beam radiation, and providing a top foil of the photovoltaic module, using an adhesive layer on top of the planarization layer. In a further embodiment, using an adhesive layer comprises laminating the top foil on the planarization layer.

### SHORT DESCRIPTION OF DRAWINGS

The present invention will be discussed in more detail below, using a number of exemplary embodiments, with reference to the attached drawings, in which

FIG. 1 shows a schematic view in cross section of a first embodiment of a PV module according to the present invention;

FIG. 2 shows a schematic view in cross section of a second embodiment of a PV module according to the present invention;

FIG. 3 shows a schematic view in cross section of a third embodiment of a PV module according to the present invention;

FIG. 4 shows a schematic view in cross section of a fourth embodiment of a PV module according to the present invention;

FIG. 5 shows a schematic view in cross section of a fifth embodiment of a PV module according to the present invention;

FIG. 6 shows a schematic view in cross section of a sixth embodiment of a PV module according to the present invention.

### DETAILED DESCRIPTION OF EXEMPLARY EMBODIMENTS

In general the present invention embodiments focus on the flexible (front-side) encapsulation of photovoltaic modules. The embodiments described below include that that the encapsulation is a front side encapsulation. It will be clear that the encapsulation may also be provided as a back side encapsulation or a combination of a front and back side encapsulation.

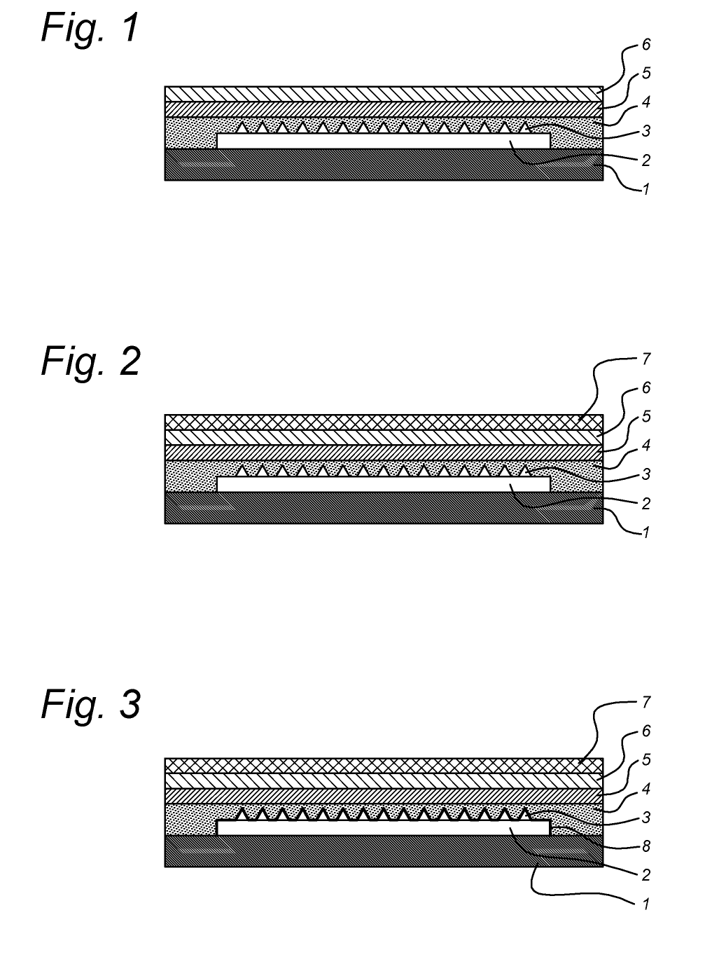

FIG. 1 is a schematic view of an embodiment of a photo-voltaic module according to the present invention. The module comprises a substrate 1 of a PV module, possibly also provided with a backside encapsulation. On the substrate 1, one or more PV cells 2 are provided, as in regular known PV modules. The PV cells 2 can be any known type of PV cell, e.g. (crystalline) silicon cells, amorphous silicon cells, Cadmium Telluride (CdTe) cells, Copper Indium Gallium Selenium (CIGS) cells, etc. On top of each PV cell 2 a texture layer 3 is present, e.g. in the form of transparent electrodes or non transparent material such as silver printed on the PV cell 2. The texture layer 3 can have any (two dimensional) structure, and may even vary in thickness over the PV cell 2 surface. The texture layer 3 may also comprise grooves in a material, etching structures, laser scribes, holes, metallization and e.g. TCO layers. On top of the PV cell 2 and texture layer 3, a planarization coating 4 is provided. This planarization layer 4 evens out the texture layer 3, such that a planar surface is provided. The thickness of the planarization layer 4 is sufficient to fully encase the textures of the texture layer 3, and is e.g. more than 20 μm, e.g. more than 40 μm, or even more than 100 μm. When in an embodiment no metallization is present, the thickness of the planarization layer 4 may be less, e.g. 5-10 μm.

On top of the planarization coating 4, an encapsulation layer is provided, which in this embodiment comprises an adhesive layer 5, and a top foil 6 (e.g. using a fluoropolymer material such as ethylene tetrafluoroethylene (ETFE)).

As the planarization coating 4 provides for a flat surface, the encapsulation layer can be formed using efficient laminating techniques: the adhesive layer 5 and top foil 6 can be attached to the PV module using simple (and fast) techniques, such as dry film lamination techniques.

The flat surface of the planarization coating 4 can be provided using a UV curable material. This allows easy and fast processing, without the need to bring the PV module to a higher temperature during a prolonged period as in prior art techniques.

The UV curable material in general is a mixture of monomers, oligomers, photo-initiators and possibly further additives, but without a solvent. This mixture is a fluid that upon exposure to UV radiation will fully polymerize into a coating to form the planarization layer 4. Depending on the specific composition, full polymerization is achieved within seconds.

In further embodiments, the UV curable material is an electron beam (EB) curable material, which polymerizes under electron beam exposure. An EB curable material in general does not require a photo-initiator to be present in the mixture.

Any fluid material that can be cured using radiation (UV light or electron beam energy) may be used in the present invention embodiments, as they all require no temperature cycle of the PV module during forming of the planarization layer 4. Materials based on free radical systems or cationic or epoxy systems may be used, see e.g. the Coatings Technology Handbook, third edition, chapter 97 ‘Radiation-Cured Coatings’.

FIG. 2 depicts a schematic cross sectional view of a further embodiment using the planarization layer 4. Because of the flatness of the semi-product with the planarization layer, the encapsulation layer protecting at least the front side of the PV module can be provided in a more cost-effective manner. As shown in the embodiment of FIG. 2, the encapsulation layer now comprises an adhesive layer 5, the top foil 6 is made of PET and provided with a (weather resistant) top coating 7. The top coating 7 can again be produced using a radiation cured material in further embodiments.

This embodiment uses other material than prior art PV module encapsulation materials, and provides a more cost efficient product.

FIG. 3 illustrates a third embodiment of a PV module (again shown in cross section), where the PV cells 2 (the active layer in the PV module) is protected by a first protection layer 8, i.e. an inorganic dielectric layer e.g. from a non-conductive transparent ceramic material. In general, and indicated in FIG. 3, the texture layers 3 are also covered by the first protection layer 8.

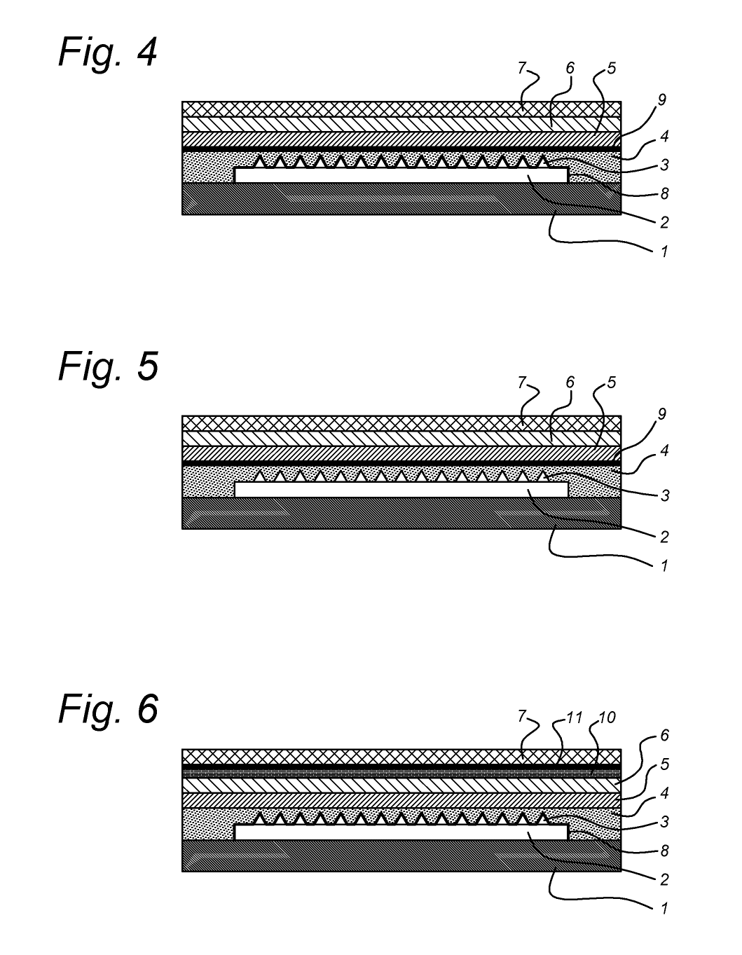

FIG. 4 shows schematically a further embodiment, which in comparison to the embodiment of FIG. 3 is provided with a second protection layer 9 (e.g. again from transparent non-conductive ceramic material) on top of the planarization layer 4.

FIG. 5 shows schematically an even further embodiment of the PV module having only a second protection layer 9 (i.e. an inorganic dielectric layer e.g. from a transparent non-conductive ceramic material) on top of the planarization layer 4.

The embodiments of FIGS. 3, 4 and 5 provide additional protection to sensitive parts of the PV module, e.g. the layer with PV cells 2, especially with regard to exposure to humidity/water.

The embodiments shown in FIGS. 3, 4 and 5 have the same basic structure of an encapsulation layer as the embodiment of FIG. 2, but the first protection layer 8 and/or second protection layer 9 are added to provide additional robustness of the PV module.

The first and/or second protection layer 8, 9 may be provided using layer deposition techniques, such as atomic layer deposition (ALD). Alternative techniques include but are not limited to Physical Vapor Deposition (PVD), and Plasma enhanced Chemical Vapor Deposition (PECVD). This allows to make the layers 8, 9 thin yet completely covering the underlying surface. These layers 8, 9 are made of e.g. SiNₓ, SiOₓN_{y}, SiOₓ, or AlOₓ.

FIG. 6 displays an even further embodiment where the top foil 6, made of e.g. PET, is also protected against moisture by an additional planarization layer 10 and a third protection layer 11 (i.e. an inorganic dielectric layer e.g. from a transparent non-conductive ceramic material). The additional planarization layer 10 ensures that the third protection layer 11 can be applied in a consistent and robust manner. The top coating 7 is then applied on top of the third protection layer 11, as mentioned above in relation to the FIG. 2 embodiment. The additional planarization layer 10 and third protection layer 11 may also be applied below the top foil 6.

The embodiments as described above enable high-speed manufacturing possibly via roll-to-roll processing. All of the embodiments are characterized by a radiation curing coating (ultra violet (UV) light or electron beam (EB)) which planarizes a texture layer 3 (like silver prints) on a front surface of active PV cells 2 and around. Consequently, this permits a top foil 6 being laminated on upper side using a thin layer 5 of lamination adhesive only. This can be accomplished using lamination manufacturing techniques known as such. In total, the manufacturing of the PV module according to the present invention embodiments then comprises a quick and cost effective coating technique (for the planarization layer 4) in combination with quick and easy lamination of the adhesive layer 5 and top foil 6. Further layers 7-11 may be added using efficient and quick layer deposition techniques, e.g. using radiation curing for the top coating 7 (and optional additional planarization layer 10), and e.g. using PECVD techniques for applying the protection layers 8, 9, 11.

The present invention embodiments have been described above with reference to a number of exemplary embodiments as shown in the drawings. Features of various embodiments may be combined to form further embodiments. Modifications and alternative implementations of some parts or elements are possible, and are included in the scope of protection as defined in the appended claims. Furthermore, the embodiments described above relate to PV modules with PV cells 2. As an alternative, the encapsulation according to the present invention embodiments may also be applied to other planar light receiving or light emitting modules, e.g. diode device based modules such as OLED screens.

1. A photovoltaic module comprising
a photovoltaic layer with one or more photovoltaic cells and an encapsulation comprising a top foil,
the photovoltaic layer being provided with a texture layer,
characterized in that the encapsulation further comprises
a planarization layer directly in contact with the photovoltaic layer and texture layer, wherein the planarization layer is a radiation curing coating.

2. The photovoltaic module according to claim 1, wherein an adhesive layer is present on top of the planarization layer, and the top foil is present on top of the adhesive layer.

3. The photovoltaic module according to claim 2, wherein the material of the top foil is selected from the group of: a fluoropolymer, a polyester, a polyamide, an acrylate, a silicone or a glass.

4. The photovoltaic module according to claim 2, further comprising a top coating on top of the top foil.

5. The photovoltaic module according to claim 4, wherein the top coating is a radiation curing coating.

6. The photovoltaic module according to claim 1, wherein the photovoltaic layer comprises a first protection layer in the form of an inorganic dielectric layer.

7. The photovoltaic module according to claim 1, wherein a second protection layer in the form of an inorganic dielectric layer is deposited on top of the planarization layer.

8. The photovoltaic module according claim 1, wherein an additional planarization layer and a third protection layer is applied to the top foil, the third protection layer being an inorganic dielectric layer.

9. Method for manufacturing a photovoltaic module, comprising
providing a PV module having a photovoltaic layer with a surface on which a texture layer is present,
providing a planarization layer directly in contact with the photovoltaic layer and texture layer,
curing the planarization layer using UV or electron beam radiation, and providing a top foil of the photovoltaic module, using an adhesive layer on top of the planarization layer.

10. Method according to claim 9, wherein using an adhesive layer comprises laminating the top foil on the planarization layer.
